(19) United States
(12) Patent Application Publication
(10) Pub. No.: US 2024/0219422 A1
(43) Pub. Date: Jul. 4, 2024

(54) ANISOTROPIC ELECTROCONDUCTIVE SHEET, METHOD FOR PRODUCING SAME, ELECTRICAL INSPECTION DEVICE, AND ELECTRICAL INSPECTION METHOD

(71) Applicant: MITSUI CHEMICALS, INC., Chuo-ku, Tokyo (JP)

(72) Inventors: Katsunori NISHIURA, Chiba-shi, Chiba (JP); Daisuke YAMADA, Hidaka-shi, Saitama (JP); Yuichi ITOU, Ichihara-shi, Chiba (JP); Masao HORI, Chiba-shi, Chiba (JP)

(73) Assignee: MITSUI CHEMICALS, INC., Chuo-ku, Tokyo (JP)

(21) Appl. No.: 18/292,379

(22) PCT Filed: Jun. 30, 2022
(86) PCT No.: PCT/JP2022/026199

§ 371 Date: Jan. 26, 2024

(30) Foreign Application Priority Data
Jul. 30, 2021 (JP) 2021-126025

(51) Int. Cl. G01R 1/04

(52) U.S. Cl. CPC G01R 1/0408

(57) ABSTRACT

This anisotropic electroconductive sheet includes: an insulating layer having a first surface, a second surface, and a plurality of through-holes penetrating between the two surfaces; a plurality of electroconductive layers disposed on the inner wall surfaces of each of the plurality of through-holes; and a plurality of electroconductive fillers filled into cavities surrounded by the electroconductive layers inside each of the plurality of through-holes. Each of the plurality of electroconductive fillers contains a crosslinked product of an electroconductive elastomer composition containing electroconductive particles and an elastomer.

### TECHNICAL FIELD

The present invention relates to an anisotropic conductive sheet, a method for producing the anisotropic conductive sheet, an electrical testing apparatus, and an electrical testing method.

### BACKGROUND ART

Semiconductor devices such as printed circuit boards to be mounted in electronic products are usually subjected to electrical testing. Typically, electrical testing is performed as follows: electrically contacting a board (with electrodes thereon) of an electrical testing apparatus with terminals of an object to be tested (herein also referred to as “test object”) such as a semiconductor device; and reading the current obtained when a predetermined voltage is applied between the terminals of the test object. Then, for the purpose of reliably performing the electrical contact between the electrodes of the board of the electrical testing apparatus and the terminals of the test object, an anisotropic conductive sheet is disposed between the board of the electrical testing apparatus and the test object.

An anisotropic conductive sheet has conductivity in the thickness direction thereof and insulating properties in the surface direction thereof, and is used as a probe (contact) in electrical testing. Such an anisotropic conductive sheet is used with an indentation load applied (load applied during a pushing process) thereon in order to reliably perform electrical connection between the board of the electrical testing apparatus and the test object. Therefore, the anisotropic conductive sheet is required to be readily elastically deformed in the thickness direction thereof.

As an anisotropic conductive sheet to satisfy such a requirement, the following is known: an electrical connector including a base sheet that includes a plurality of through holes passing through the base sheet in the thickness direction, a plurality of conductive parts disposed in the through holes, and a plurality of conductive protrusions covering the end surfaces of the conductive parts (see, for example, Patent Literature (hereinafter, referred to as PTL) 1). PTL 1 mentions that the conductive part may be a metal thin film (plated film) formed on the inner wall surface of the through hole.

### CITATION LIST

### Patent Literature

PTL 1

Japanese Patent Application Laid-Open No. 2020-27859

### SUMMARY OF INVENTION

### Technical Problem

During electrical testing, for the purpose of reliably performing the electrical contact, an indentation load is applied with a test object disposed on the surface of the anisotropic conductive sheet.

However, in an anisotropic conductive sheet as described in PTL 1, the metal thin films (conductive layers joined to the inner wall surfaces of the through holes) formed on the walls of a plurality of holes are more likely to crack or peel off due to repeated pressurization and depressurization during the pushing process; thus poor conduction is more likely to occur. As a result, there is also a problem such that variations in resistance values between the conductive layers are more likely to occur.

The present invention has been made in view of the above problems. An object of the present invention is to provide an anisotropic conductive sheet that can prevent cracking and peeling off of the conductive layer thereof and maintain satisfactory conductivity even after repeated pressurization and depressurization during the pushing process, a method for producing the anisotropic conductive sheet, and an electrical testing apparatus and an electrical testing method using the anisotropic conductive sheet.

### Solution to Problem

The above-described object can be achieved by the following configurations.

An anisotropic conductive sheet of the present invention includes:
an insulating layer including a first surface located on one side in a thickness direction of the insulating layer, a second surface located on another side in the thickness direction, and a plurality of through holes each extending between the first surface and the second surface; a plurality of first conductive layers respectively disposed on inner wall surfaces of the plurality of through holes; a plurality of conductive fillers respectively filling cavities inside the plurality of through holes, each of the cavities being surrounded by a corresponding one of the first conductive layers, in which
each of the plurality of conductive fillers contains a cross-linked product of a conductive elastomer composition that contains a conductive particle and an elastomer.

A method for producing an anisotropic conductive sheet of the present invention includes: preparing an insulating layer including a first surface located on one side in a thickness direction of the insulating layer, a second surface located on another side in the thickness direction, and a plurality of through holes each extending between the first surface and the second surface; forming a conductive layer continuously on inner wall surfaces of the plurality of through holes and on the first surface; filling insides of the plurality of through holes of the insulating layer, on which the conductive layer is formed, with a conductive elastomer composition containing a conductive particle and an elastomer; and forming a plurality of first grooves on or above the first surface of the insulating layer filled with the conductive elastomer composition or with a cross-linked product of the conductive elastomer composition, and dividing the conductive layer into a plurality of conductive layers.

### Advantageous Effects of Invention

The present invention is capable of providing an anisotropic conductive sheet that can prevent cracking and peeling off of the conductive layer thereof and maintain satisfactory conductivity even after repeated pressurization and depressurization during the pushing process, a method for producing the anisotropic conductive sheet, and an electrical testing apparatus and an electrical testing method using the anisotropic conductive sheet.

### BRIEF DESCRIPTION OF DRAWING

FIG. 1A is a partial plan view illustrating an anisotropic conductive sheet according to the present embodiment, and FIG. 1B is a partially enlarged cross-sectional view of the anisotropic conductive sheet of FIG. 1A taken along line 1B-1B;

FIG. 2 is a partially enlarged cross-sectional view of the anisotropic conductive sheet of FIG. 1A taken along line 1B-1B;

FIGS. 3A to 3D are partially enlarged cross-sectional views illustrating a method for producing the anisotropic conductive sheet according to the present embodiment;

FIGS. 4A and 4B are partially enlarged cross-sectional views illustrating the method for producing the anisotropic conductive sheet according to the present embodiment;

FIG. 5A is a cross-sectional view illustrating an electrical testing apparatus according to the present embodiment, and FIG. 5B is a bottom view illustrating an example of a test object;

FIG. 6 is a partially enlarged cross-sectional view of an anisotropic conductive sheet according to a variation;

FIGS. 7A and 7B are partially enlarged plan views of the vicinities of through holes on a first surface of an anisotropic conductive sheet according to a variation;

FIG. 8 is a partially enlarged plan view of a first surface of an anisotropic conductive sheet according to a variation;

FIG. 9 is a partially enlarged cross-sectional view of an anisotropic conductive sheet according to a variation; and

FIG. 10 schematically illustrating a method of measuring an electrical resistance value using the electrical testing apparatus of FIG. 5A.

### DESCRIPTION OF EMBODIMENTS

### 1. Anisotropic Conductive Sheet

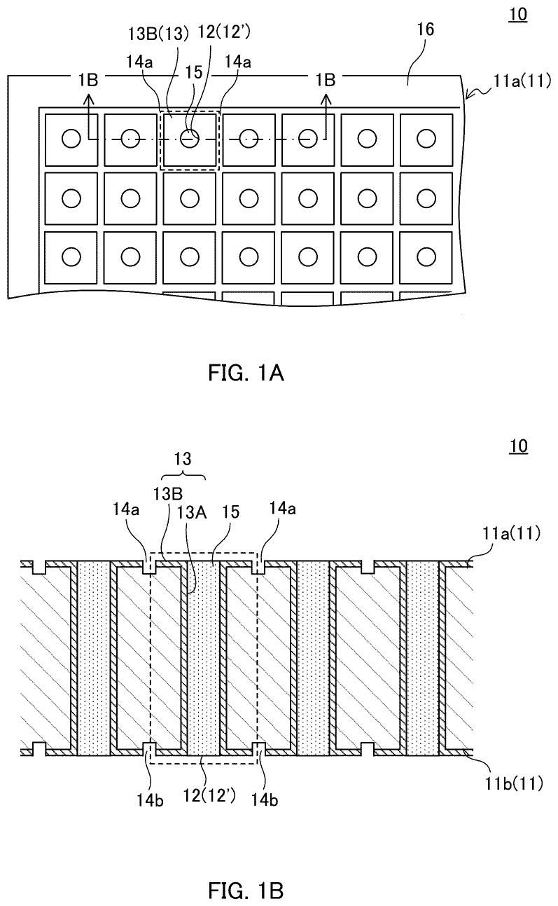

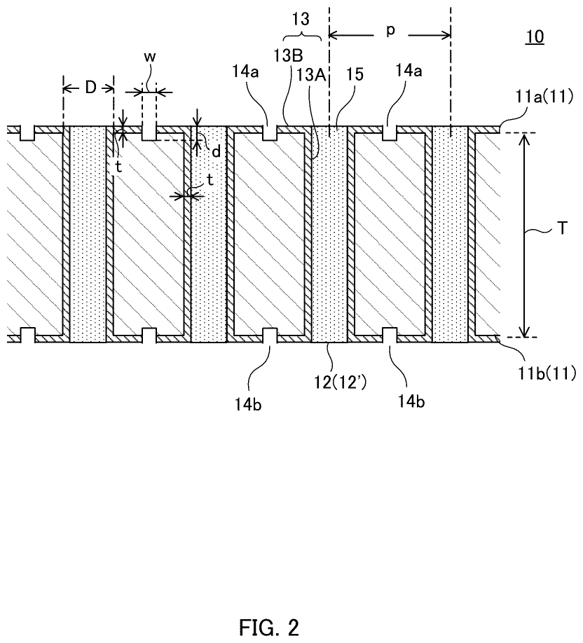

FIG. 1A is a partially enlarged plan view of anisotropic conductive sheet 10 according to the present embodiment, and FIG. 1B is a partially enlarged cross-sectional view of anisotropic conductive sheet 10 of FIG. 1A taken along line 1B-1B. FIG. 2 is a partially enlarged cross-sectional view of anisotropic conductive sheet 10 of FIG. 1A taken along line 1B-1B. The following drawings are all schematic diagrams, and the scale and the like thereof differ from the actual size.

As illustrated in FIGS. 1A and 1B, anisotropic conductive sheet 10 includes the following: insulating layer 11 including first surface 11a, second surface 11b, and a plurality of through holes 12 each extending between first surface 11a and second surface 11b (i.e., passing through the sheet from first surface 11a to second surface 11b); a plurality of first conductive layers 13A respectively disposed on the inner wall surfaces of the plurality of through holes 12, a plurality of second conductive layers 13B each disposed on first surface 11a or second surface 11b and each continuous with (one or more) first conductive layers 13A; a plurality of first grooves 14a each disposed between second conductive layers 13B and a plurality of second grooves 14b each disposed between second conductive layers 13B; a plurality of conductive fillers 15 each filling the inside of one of through holes 12 (a plurality of cavities 12′ each surrounded by first conductive layer 13A). First conductive layer 13A (on the inner wall surface of through hole 12) and second conductive layers 13B (on first surface 11a and second surface 11b) disposed continuously with first conductive layer 13A function as one conductive layer 13 (the portion in the dashed line in FIG. 1B).

In the present embodiment, a test object is preferably disposed on first surface 11a of insulating layer 11 (one surface of anisotropic conductive sheet 10).

### 1-1. Insulating Layer 11

Insulating layer 11 includes first surface 11a located on one side in the thickness direction of the insulating layer, second surface 11b located on the other side in the thickness direction, and the plurality of through holes 12 each extending between first surface 11a and second surface 11b (see FIGS. 1A and 1B).

Insulating layer 11 has elasticity such that it is elastically deformed when pressure is applied in the thickness direction. That is, insulating layer 11 preferably includes at least an elastic layer. The elastic layer preferably contains a cross-linked product of an elastomer composition (also referred to as “cross-linked elastomer composition”).

The elastomer composition may contain any elastomer. Preferred examples of the elastomer include silicone rubber, urethane rubber (urethane polymer), acrylic rubber (acrylic polymer), ethylene-propylene-diene copolymer (EPDM), chloroprene rubber, styrene-butadiene copolymer, acrylic nitrile-butadiene copolymer, polybutadiene rubber, natural rubber, polyester thermoplastic elastomer, olefin thermoplastic elastomer, and fluorine rubber. In particular, silicone rubber is preferred. The silicone rubber may be either an addition type, a condensation type, or a radical type.

The elastomer composition may further contain a crosslinking agent, as necessary. The crosslinking agent is appropriately selected in accordance with the type of elastomer. Examples of the crosslinking agent for the silicone rubber include addition reaction catalysts such as metals, metal compounds, and metal complexes (for example, platinum, platinum compounds, and the complexes thereof) having catalytic activity for hydrosilylation reactions; and organic peroxides such as benzoyl peroxide, bis-2,4-dichlorobenzoyl peroxide, dicumylperoxide, and di-t-butyl peroxide. Examples of the crosslinking agent for acrylic rubber (acrylic polymer) include epoxy compounds, melamine compounds, and isocyanate compounds.

Examples of the cross-linked product of a silicone rubber composition include addition cross-linked products of silicone rubber compositions each containing organopolysiloxane having a hydrosilyl group (SiH group), organopolysiloxane having a vinyl group, and an addition reaction catalyst; addition cross-linked products of silicone rubber compositions each containing organopolysiloxane having a vinyl group, and an addition reaction catalyst; and cross-linked products of silicone rubber compositions each containing organopolysiloxane having a SiCH₃ group and an organic peroxide curing agent.

The elastomer composition may further contain at least one additional component such as a tackifier, a silane coupling agent, and/or a filler, as necessary.

The glass transition temperature of the cross-linked elastomer composition is not limited, but from the viewpoint of preventing or reducing the damage of the terminal of a test object, the glass transition temperature is preferably −40° C. or lower, more preferably −50° C. or lower. The glass transition temperature can be measured in compliance with JIS K 7095:2012.

The storage elastic modulus of the cross-linked elastomer composition at 25° C. is preferably 1.0×10⁷ Pa or less, more preferably 1.0×10⁵ to 9.0×10⁶ Pa. The storage elastic modulus of the cross-linked elastomer composition can be measured in compliance with JIS K 7244-1:1998/ISO6721-1:1994.

The glass transition temperature and the storage elastic modulus of the cross-linked elastomer composition can be adjusted by the composition of the elastomer composition.

The axial direction of through hole 12 may be substantially parallel to the thickness direction of insulating layer 11 (for example, the angle of through hole 12 with respect to the thickness direction of insulating layer 11 is 10° or less), or may be inclined (for example, inclined at an angle of more than 10° and 50° or less, preferably an angle of 20° to 45°, with respect to the thickness direction of insulating layer 11). In the present embodiment, the axial direction of through hole 12 is substantially parallel to the thickness direction of insulating layer 11 (see FIG. 1B). Herein, the axial direction refers to the direction of a line connecting the center of gravity (or center) of the openings of through hole 12 on the first surface 11a side with the center of gravity (or center) of the opening on the second surface 11b side.

The opening of through hole 12 on first surface 11a may have any shape, which may be, for example, of a quadrangle or another polygon. In the present embodiment, the shape of the opening of through hole 12 on first surface 11a is circular (see FIGS. 1A and B). In addition, the shape of the opening of through hole 12 on the first surface 11a side and the shape of the opening of through hole 12 on the second surface 11b side may be the same as or different from each other. The shapes are preferably the same from the viewpoint of connection stability to an electronic device to be measured.

Equivalent circle diameter D of the opening of through hole 12 on the first surface 11a side is not limited as long as center-to-center distance (pitch) p of the openings of through holes 12 is set to fall within a range described below. Equivalent circle diameter D is preferably 1 to 330 μm, more preferably 2 to 200 μm, and even more preferably 10 to 100 μm (see FIG. 2), for example. Equivalent circle diameter d of the opening of through hole 12 on the first surface 11a side is the equivalent circle diameter of the opening of through hole 12 as viewed along the axial direction of through hole 12 from the first surface 11a side (i.e., the diameter of a perfect circle corresponding to the area of the opening).

Equivalent circle diameter D of the opening of through hole 12 on the first surface 11a side may be the same as or different from equivalent circle diameter D of the opening of through hole 12 on the second surface 11b side.

Center-to-center distance (pitch) p of the openings of through holes 12 on the first surface 11a side is not limited, and may be appropriately set in accordance with the pitch of the terminals of a test object (see FIG. 2). As a test object, a high bandwidth memory (HBM) has the pitch between the terminals of 55 μm, and a package on package (POP) has the pitch between the terminals of 400 to 650 μm, center-to-center distance p of the openings of through holes 12 may be, for example, 5 to 650 μm. In particular, from the view point of eliminating the need for the alignment of the terminals of the test object (from the view point of achieving alignment free), center-to-center distance p of the openings of through holes 12 on the first surface 11a side is preferably 5 to 55 μm. Center-to-center distance p of the openings of through holes 12 on the first surface 11a side refers to the minimum value among the center-to-center distances of through holes 12 on the first surface 11a side. The center of an opening of through hole 12 is the center of gravity of the opening. In addition, center-to-center distance p of the openings of through holes 12 may be constant or vary in the axial direction.

The ratio (T/D) of the length of through hole 12 in the axial direction (i.e., thickness T of insulating layer 11) to equivalent circle diameter D of the opening of through hole 12 on the first surface 11a side is not limited, but is preferably 3 to 40 (see FIG. 2).

The thickness of insulating layer 11 is not limited as long as satisfactory insulating properties can be obtained in non-conducting portions, and is, for example, preferably 40 to 700 μm, more preferably 100 to 400 μm.

### 1-2. Conductive Layer 13 (First Conductive Layer 13A and Second Conductive Layer 13B)

One conductive layer 13 is disposed so as to correspond to one or more through holes 12 (or cavities 12′) (see FIG. 1B). Specifically, conductive layer 13 includes first conductive layer 13A disposed on the inner wall surface of through hole 12, and second conductive layers 13B each disposed on first surface 11a or second surface 11b (around the opening of the corresponding through hole 12) and each continuous with one or more first conductive layers 13A. The two adjacent conductive layers 13 and 13 (or the two second conductive layers 13B and 13B) are insulated from each other by first groove 14a or second groove 14b (see FIG. 1B). That is, a unit of conductive layer 13 in a dashed line functions as one conductive path (see FIGS. 1A and 1B).

The material for first conductive layer 13A and the material for second conductive layer 13B may be the same as or different to each other, but from the viewpoint of easy manufacture and stable conduction, the materials are preferably the same.

The volume resistivity of the material for conductive layer 13 (first conductive layer 13A, second conductive layer 13B) is not limited as long as satisfactory conduction can be obtained. The volume resistivity is preferably, for example, 1.0×10⁻⁴ Ω·m or less, more preferably 1.0×10⁻⁵ to 1.0×10⁹ Ω·m. The volume resistivity of the material for conductive layer 13 can be measured by the method described in ASTM D 991.

Any material whose volume resistivity satisfies the above range may be used as the material for conductive layer 13. Examples of the material for conductive layer 13 include metal materials such as copper, gold, platinum, silver, nickel, tin, iron, and alloys thereof, and carbon materials such as carbon black. In particular, conductive layer 13 preferably contains at least one member selected from the group consisting of gold, silver, and copper (as a main component), from the high conductivity and flexibility of the material. Containing a material as a main component means, for example, that the content of the material is 70 mass % or more, preferably 80 mass % or more, based on conductive layer 13.

The thickness of conductive layer 13 may be within a range such that satisfactory conduction can be obtained and through hole 12 is not blocked (a range such that cavity 12′ can be formed). In addition, the thickness of conductive layer 13 (particularly, second conductive layer 13B) may be set within a range such that when pressing is performed in the thickness direction of insulating layer 11, conductive layers 13 (particularly the second conductive layers 13B) with first groove 14a or second groove 14b placed therebetween do not come into contact with each other. Specifically, the thickness of conductive layer 13 (particularly second conductive layer 13B) is preferably less than the widths and depths of first groove 14a and second groove 14b.

Specifically, the thickness of conductive layer 13 may be 0.1 to 5 μm. When the thickness of conductive layer 13 is a certain value or more, satisfactory conduction is more likely to be obtained, and when the thickness is less than a certain value, through hole 12 is less likely to be blocked and the terminal of a test object is less likely to be damaged due to contact with conductive layer 13. Thickness t of conductive layer 13 on first surface 11a and second surface 11b (that is, thickness of second conductive layer 13B) refers to the thickness in the direction parallel to the thickness direction of insulating layer 11. Thickness t of conductive layer 13 on the inner wall surface of through hole 12 (that is, thickness of first conductive layer 13A) is the thickness in the direction orthogonal to the thickness direction of insulating layer 11 (see FIG. 2).

### 1-3. First Groove 14a and Second Groove 14b

First groove 14a and second groove 14b are grooves (recess) formed on one surface and the other surface of anisotropic conductive sheet 10, respectively. Specifically, first groove 14a is disposed between second conductive layers 13B (or conductive layers 13) on or above first surface 11a, and insulates the second conductive layers from each other. Second groove 14b is disposed between second conductive layers 13B (or conductive layers 13) on or above second surface 11b, and insulates the second conductive layers from each other.

The cross-sectional shape of first groove 14a (or second groove 14b) in the direction orthogonal to the extending direction of the groove is not limited, and may be quadrangular, semicircular, U-shaped, or V-shaped. In the present embodiment, the cross-sectional shape of first groove 14a (or second groove 14b) is a quadrangular.

Width w and depth d of first groove 14a (or second groove 14b) are preferably set to fall within a range such that when anisotropic conductive sheet 10 is pressed in the thickness direction thereof, second conductive layer 13B on one side and second conductive layer 13B on the other side with first groove 14a (or second groove 14b) therebetween do not come into contact with each other (see FIG. 2).

Specifically, when anisotropic conductive sheet 10 is pressed in the thickness direction, second conductive layer 13B on one side and second conductive layer 13B on the other side with first groove 14a (or second groove 14b) therebetween approach each other and are more likely to come into contact with each other. Therefore, width w of first groove 14a (or second groove 14b) is preferably more than the thickness of second conductive layer 13B (or conductive layer 13). Width w is more preferably 2 to 40 times the thickness of second conductive layer 13B (or conductive layer 13). Width w of first groove 14a (or second groove 14b) is the maximum width in a direction orthogonal to the direction in which first groove 14a (or second groove 14b) extends in first surface 11a (or second surface 11b) (see FIG. 2).

Depth d of first groove 14a (or second groove 14b) may be the same as or more than the thickness of second conductive layer 13B (or conductive layer 13). That is, the deepest part of first groove 14a (or second groove 14b) may be located at first surface 11a of insulating layer 11, or located inside insulating layer 11. In particular, from the viewpoint of easily setting depth d to fall within a range such that second conductive layer 13B (or conductive layer 13) on one side and second conductive layer 13B (conductive layer 13) on the other side with first groove 14a (or second groove 14b) placed therebetween do not contact with each other, depth d of first groove 14a (or second groove 14b) is preferably more than the thickness of second conductive layer 13B (conductive layer 13). Depth d is more preferably 1.5 to 100 times the thickness of second conductive layer 13B (conductive layer 13). Depth d of first groove 14a (or second groove 14b) refers to the depth from the surface of second conductive layer 13B (or conductive layer 13) to the deepest part of the groove in the direction parallel to the thickness direction of insulating layer 11 (see FIG. 2).

Width w and depth d of first groove 14a or second groove 14b may be the same as or different from each other.

### 1-4. Conductive Filler 15

Conductive filler 15 fills cavity 12′ surrounded by first conductive layer 13A (or conductive layer 13) of through hole 12, and can prevent peeling off of first conductive layer 13A (or conductive layer 13) while maintaining conductivity.

From the viewpoint of easily maintaining conductivity, conductive filler 15 preferably fills 50% or more of the volume in cavity 12′, more preferably fills the entire cavity 12′. That is, it is preferred that the end of conductive filler 15 on the first surface 11a side (or the end on the second surface 11b side) is substantially flush with first surface 11a (or second surface 11b) of insulating layer 11.

Conductive filler 15 contains a cross-linked product of a conductive elastomer composition (also referred to as “cross-linked conductive elastomer composition”) which contains conductive particles and an elastomer.

The material for the conductive particles is not limited. Examples of the material include particles of metal such as copper, gold, platinum, silver, nickel, tin, iron, and alloys thereof, and particles of carbon such as carbon black. In particular, the conductive particles preferably contain at least one member selected from the group consisting of gold, silver, and copper (as a main component), from the high conductivity and flexibility of the material. Containing a material as a main component means, for example, that the content of the material is 50 mass % or more, preferably 60 mass % or more, based on the conductive elastomer composition. The material for the conductive particles may be the same as or different from the materials for first conductive layer 13A and second conductive layer 13B (or conductive layer 13).

The average particle diameter of the conductive particles is not limited as long as the conductive particles can fill cavity 12′, but is, for example, approximately 0.3 to 30% of the equivalent circle diameter of through hole 12 on the first surface 11a side. Specifically, the average particle diameter of the conductive particles may be approximately 0.3 to 30 μm. The average particle diameter of the conductive particles is the 50% particle diameter (D50) measured with a laser diffraction particle size analyzer. The average particle diameter is the particle size at the point where the cumulative amount becomes 50 mass % starting from the smaller particle diameter in the volume-based particle size distribution.

Any type of elastomer may be used, and the same elastomer used in the elastomer composition for insulating layer 11 can be used. The type of elastomer used in the conductive elastomer composition may be the same as or different from the type of elastomer used in the elastomer composition for insulating layer 11. In particular, silicone rubber is preferred from the viewpoint of flexibility. The silicone rubber may be either an addition type, a condensation type, or a radical type, as described above.

The content of the elastomer is preferably 5 to 50 mass % based on the total amount of the conductive particles and the elastomer. When the content of the elastomer is 5 mass % or more, the adhesion to first conductive layer 13A (or conductive layer 13) is more likely to increase, and the cross-linked conductive elastomer composition has satisfactory flexibility; therefore, cracking and peeling off of first conductive layer 13A (or conductive layer 13) can be further prevented. When the content of the elastomer is 50 mass % or less, conductivity is less likely to be impaired; therefore, satisfactory conductivity can be obtained even when cracking occurs in first conductive layer 13A (or conductive layer 13),

The conductive elastomer composition may further contain at least one additional component such as a crosslinking agent, as necessary. The type of crosslinking agent is not limited, and the same crosslinking agent as used in the elastomer composition for insulating layer 11 can be used.

The storage elastic modulus of the cross-linked conductive elastomer composition at 25° C. is not limited, but usually tends to become higher than the storage elastic modulus of the cross-linked elastomer composition for insulating layer 11 at 25° C. However, from the viewpoint of avoiding problems that would be caused by concentration of pressure on conductive filler 15 during the pushing process, the storage elastic modulus is preferably appropriately low. Specifically, the storage elastic modulus of the cross-linked conductive elastomer composition at 25° C. is preferably 1 to 300 MPa, more preferably 2 to 200 MPa. The storage elastic modulus can be measured in a compressive deformation mode.

The storage elastic modulus of the cross-linked conductive elastomer composition can be adjusted by the composition of the elastomer composition. For example, reducing the content of the conductive particles can lower the storage elastic modulus of the cross-linked product of the composition.

The cross-linked conductive elastomer composition is preferably has a certain level of conductivity or more. Specifically, the volume resistivity of the cross-linked conductive elastomer composition is preferably 10⁻² Ω·m or less. When the volume resistivity of the cross-linked conductive elastomer composition falls within the above range, the electrical connection between conductive layer 13 (or second conductive layer 13B) and the terminal of a test object is less likely to be disturbed even when the conductive elastomer composition remains on first surface 11a of insulating layer 11 or the like during the production process of anisotropic conductive sheet 10. From the same viewpoint, the volume resistivity of the cross-linked conductive elastomer composition is more preferably 1×10⁻⁸ to 1×10⁻² Ω·m. The volume resistivity can be measured by the same method as above.

### 1-5. Effect

Anisotropic conductive sheet 10 of the present embodiment includes conductive filler 15 filling cavity 12′ (a cavity originating from through hole 12) surrounded by conductive layer 13 (or first conductive layer 13A). Conductive filler 15 satisfactorily adhere to conductive layer 13 (or first conductive layer 13A), thereby reinforcing the layer. Therefore, during electrical testing, cracking or peeling off of conductive layer 13 (from the inner wall surface of through hole 12) can be prevented even after repeated pressurization and depressurization during the pushing process, thereby achieving stable electrical connection.

### 2. Method for Producing Anisotropic Conductive Sheet

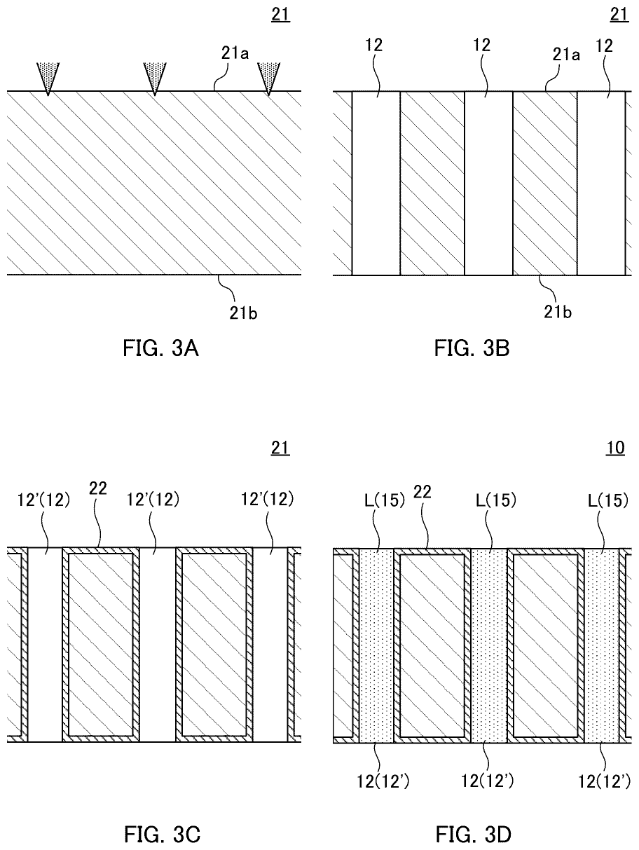

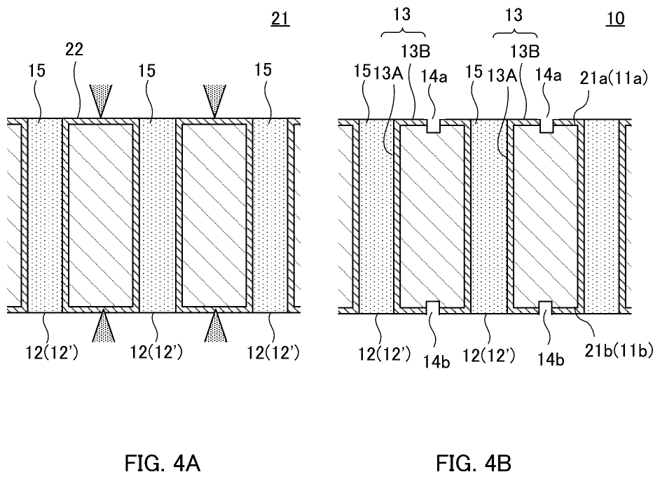

FIGS. 3A to 3D, 4A and 4B are schematic cross-sectional views illustrating a method for producing anisotropic conductive sheet 10 according to the present embodiment.

Anisotropic conductive sheet 10 according to the present embodiment can be produced, for example, by the following steps: 1) preparing insulating sheet 21 (insulating layer) including a plurality of through holes 12 (see FIGS. 3A and 3B); 2) forming one continuous conductive layer 22 on the surface of insulating sheet 21 (see FIG. 3C); 3) filling the insides of the plurality of through holes 12 of the insulating sheet 21—on which conductive layer 22 is formed—with a conductive elastomer composition (see FIG. 3D); and 4) forming first grooves 14a and second grooves 14b respectively on first surface 21a and second surface 21b of insulating sheet 21 filled with the conductive elastomer composition, and dividing conductive layer 22 into a plurality of conductive layers 13 (see FIGS. 4A and 4B). Conductive layer 13 is the above-described conductive layer 13 (first conductive layer 13A, second conductive layer 13B) (see the dashed line portion in FIG. 1B).

### Step 1)

First, insulating sheet 21 is prepared (see FIG. 3A). Insulating sheet 21 is, for example, a sheet containing the above-described cross-linked elastomer composition.

Next, a plurality of through holes 12 are formed in insulating sheet 21 (see FIG. 3B).

Any method may be used for forming through holes 12. For example, a method of mechanically forming holes (for example, press processing or punching) or a laser processing method may be used. In particular, it is more preferable to form through holes 12 by a laser processing method, which can form fine through holes 12 with high shape accuracy.

As the laser, an excimer laser, a carbon dioxide laser, a YAG laser, or the like, which can perforate resin with high accuracy, can be used. In particular, an excimer laser is preferably used. The pulse width of the laser is not limited, and the laser may be a microsecond laser, a nanosecond laser, a picosecond laser, or a femtosecond laser. In addition, the wavelength of the laser is also not limited.

In laser processing, the opening diameter of through hole 12 tends to become larger on the laser irradiation surface of insulating layer 11, where the layer is irradiated with the laser for the longest time. In other words, the through hole tends to have a tapered shape in which the opening diameter increases from the inside of insulating layer 11 toward the laser irradiation surface. From the viewpoint of avoiding such a tapered shape as much as possible, laser processing may be performed on insulating sheet 21 further including a sacrificial layer (not illustrated) on the surface to be irradiated with laser. The method for performing laser processing on insulating sheet 21 including a sacrificial layer can be performed, for example, by a method similar to that described in WO2007/23596.

### Step 2)

Next, one continuous conductive layer 22 is formed on or over the entire surface of insulating sheet 21, in which the plurality of through holes 12 are formed (see FIG. 3C). Specifically, conductive layer 22 is formed continuously on the inner wall surfaces of the plurality of through holes 12, and on first surfaces 21a and second surfaces 21b around the openings of the through holes in insulating sheet 21. As a result, a plurality of cavities 12′—each surrounded by conductive layer 13-corresponding to the plurality of through holes 12 are formed.

Any method may be used for forming conductive layer 22; however, it is preferable to use a plating method (for example, electroless plating or electrolytic plating), which can form thin conductive layer 22 having a uniform thickness without blocking through holes 12.

### Step 3)

Next, the insides of cavities 12′ (each surrounded by conductive layer 13 and inside through holes 12) in the obtained insulating sheet 21 are filled with conductive elastomer composition L (see FIG. 3D).

Conductive elastomer composition L may further contain a solvent and the like in addition to the conductive particles and an elastomer.

The viscosity of conductive elastomer composition L at 25° C. is not limited, but from the viewpoint of filling the insides of cavities 12′, the viscosity may be, for example, 100 Pa·s or less, preferably 10 to 80 Pa·s. The viscosity of the conductive elastomer composition can be measured with a known viscometer at 25° C.

Any method may be used for filling the cavity with conductive elastomer composition L, but, for example, the following method can be used: a method in which conductive elastomer composition L is applied on or above first surface 21a, and then the insides of cavities 12′ are vacuumed from the second surface 21b side.

Conductive elastomer composition L filling the plurality of cavities 12′ is then cross-linked. A conductive elastomer composition L containing a solvent is preferably further dried. The crosslinking method depends on the type of elastomer and crosslinking agent, but may be, for example, heating. The heating temperature may be, for example, 100 to 200° C. in the case of silicone rubber.

### Step 4)

Next, first grooves 14a and second grooves 14b are respectively formed on first surface 21a and second surface 21b of insulating sheet 21, and conductive layer 22 is divided into a plurality of conductive layers 13 (or second conductive layer 13B) (see FIGS. 4A and B). As a result, the plurality of conductive layers 13 illustrated in FIG. 1B are formed.

Any method may be used for forming the plurality of first grooves 14a and second grooves 14b. For example, the plurality of first grooves 14a and the plurality of second grooves 14b are preferably formed by a laser processing method. In the present embodiment, on first surface 21a (or second surface 21b), the plurality of first grooves 14a (or the plurality of second grooves 14b) may be formed in a lattice shape.

The method for producing anisotropic conductive sheet 10 according to the present embodiment may further include steps in addition to those described above, as necessary. For example, a step of 5) pretreatment to facilitate formation of conductive layer 22 may be performed between the steps 2) and 3).

### Step 5)

It is preferable to perform desmear treatment (pretreatment) on the insulating sheet 21 including the plurality of through holes 12 formed therein to facilitate formation of conductive layer 22. Desmear treatment can be performed by a wet method or a dry method, and either method may be used.

As the wet desmear treatment, in addition to alkali treatment, any known wet process, such as a sulfuric acid method, a chromic acid method, or a permanganate method, may be employed.

Examples of the dry desmear treatment include plasma processing. For example, when insulating sheet 21 is formed from a cross-linked product of a silicone elastomer composition, performing plasma treatment on insulating sheet 21 not only enables ashing/etching but also oxidizes the surface of silicone to form a silica film. By forming the silica film, a plating solution is more likely to enter through hole 12, and the adhesion between conductive layer 22 and the inner wall surface of through hole 12 can be increased.

Oxygen plasma treatment can be performed by using, for example, a plasma asher, a high frequency plasma etching device, or a microwave plasma etching device.

In addition, the crosslinking of the conductive elastomer composition may be performed after the step 4), not in the step 3).

The obtained anisotropic conductive sheet is preferably be used for electrical testing.

### 3. Electrical Testing Apparatus and Electrical Testing Method

### 3-1. Electrical Testing Apparatus

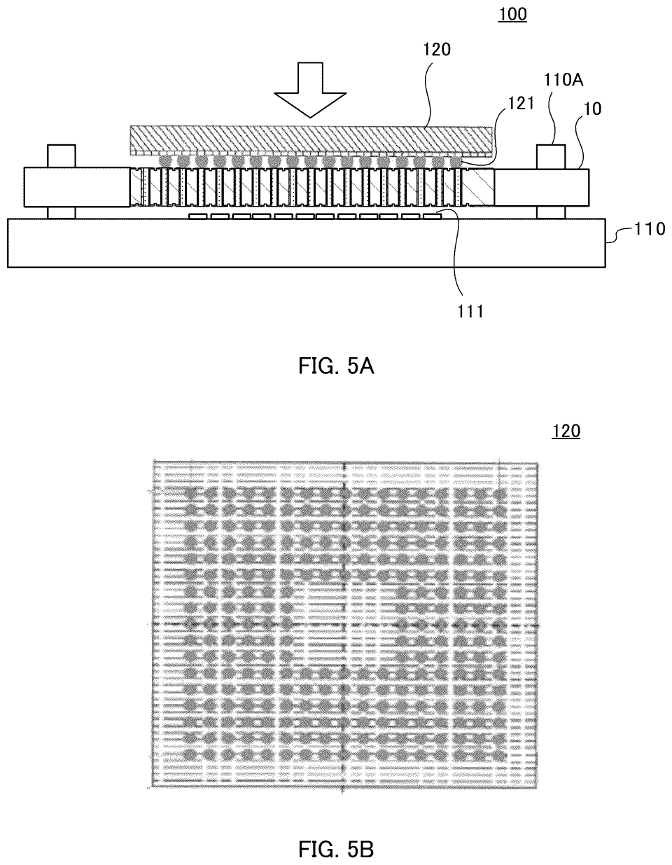

FIG. 5A is a cross-sectional view illustrating an example of electrical testing apparatus 100 according to the present embodiment, and FIG. 5B is a bottom view illustrating an example of test object 120 used for an electrical testing method.

Electrical testing apparatus 100 uses anisotropic conductive sheet 10 of FIG. 1B and inspects the electrical characteristics (such as conduction) between terminals 121 (measurement points) of test object 120, for example. FIG. 5A also illustrates test object 120 for describing the electrical testing method.

As illustrated in FIG. 5A, electrical testing apparatus 100 includes anisotropic conductive sheet 10 and testing board 110 including a plurality of electrodes.

Testing board 110 includes, at the surface facing test object 120, a plurality of electrodes 111 each facing a corresponding measurement point of test object 120.

Anisotropic conductive sheet 10 is disposed on or above testing board 110 at the surface where electrodes 111 are disposed, in such a way that electrodes 111 are in contact with conductive layers 13 of anisotropic conductive sheet 10 on the second surface 11b side.

In electrical testing apparatus 100, anisotropic conductive sheet 10 can be positioned to be disposed on or above testing board 110 by inserting guide pins 110A of testing board 110 through the positioning holes (not illustrated) of anisotropic conductive sheet 10. Then, test object 120 is disposed on or above anisotropic conductive sheet 10, and the components can be fixed by applying pressure with a pressure jig.

Test object 120 is not limited, but examples thereof include various semiconductor devices (semiconductor packages) such as HBM and POP, electronic components, and printed boards. When test object 120 is a semiconductor package, the measurement point may be a bump (terminal). In addition, when test object 120 is a printed board, the measurement point may be a measurement land or a component mounting land provided on the conductive pattern. An example of test object 120 is, for example, a chip including a total of 264 solder ball electrodes (material of lead-free solder) with a diameter of 0.2 mm and a height of 0.17 mm, arranged at a pitch of 0.3 mm (see FIG. 5B).

### 3-2. Electrical Testing Method

An electrical testing method using electrical testing apparatus 100 of FIG. 5A is described below.

As illustrated in FIG. 5A, the electrical testing method according to the present embodiment includes a step of stacking test object 120 and testing board 110 including electrodes 111 via anisotropic conductive sheet 10, and electrically connecting electrodes 111 of testing board 110 with terminals 121 of test object 120 via anisotropic conductive sheet 10.

When the above-described step is performed, test object 120 may be pressurized for contacting, or the stacked components may be brought into contact with anisotropic conductive sheet 10 in a heated atmosphere, as necessary, from the viewpoint of facilitating satisfactory conductivity between electrodes 111 of testing board 110 and terminals 121 of test object 120 via anisotropic conductive sheet 10.

### 3-3. Effect

Anisotropic conductive sheet 10 according to the present embodiment contains conductive filler 15, containing a cross-linked conductive elastomer composition, filling the insides of cavities 12′ (insides of through holes 12). As a result, cracking and peeling off of conductive layer 13 can be prevented to maintain satisfactory conductivity even after repeated pressurization and depressurization during the pushing process. As a result, accurate electrical testing can be performed.

### Variations

The above embodiment describes an example in which insulating layer 11 is formed of an elastic layer containing a cross-linked elastomer composition; however, the present invention is not limited thereto. Insulating layer 11 may further contain at least one additional layer, such as a heat-resistant resin layer, as long as the insulating layer can be elastically deformed.

For example, insulating layer 11 contains at least an elastic layer containing a cross-linked elastomer composition, and preferably further contains a heat-resistant resin layer within a range that does not impair overall elasticity. The heat-resistant resin layer contains a heat-resistant resin composition having a glass transition temperature higher than that of the cross-linked elastomer composition in the elastic layer.

That is, in general, conductive filler 15 filling through hole 12 (or cavity 12′) can have a higher storage elastic modulus than that of the cross-linked elastomer composition in insulating layer 11. Therefore, during electrical testing, the pressure during the pushing process is more likely to concentrate on the part where conductive filler 15 is located, and conductive filler 15 is less likely to return to the original shape even when the pressure is removed. As a result, a gap is more likely to be formed in the thickness direction of the sheet in the vicinity of opening 12a of through hole 12 (or cavity 12′); thus, maintaining satisfactory conductivity may become difficult. On the other hand, when insulating layer 11 further contains heat-resistant resin layer 11Y, the pressure during the pushing process is less likely to concentrate excessively on conductive filler 15. A gap is thus less likely to be formed in the thickness direction of the sheet in the vicinity of opening 12a of through hole 12 (or cavity 12′); thus, the conductivity is less likely to be impaired.

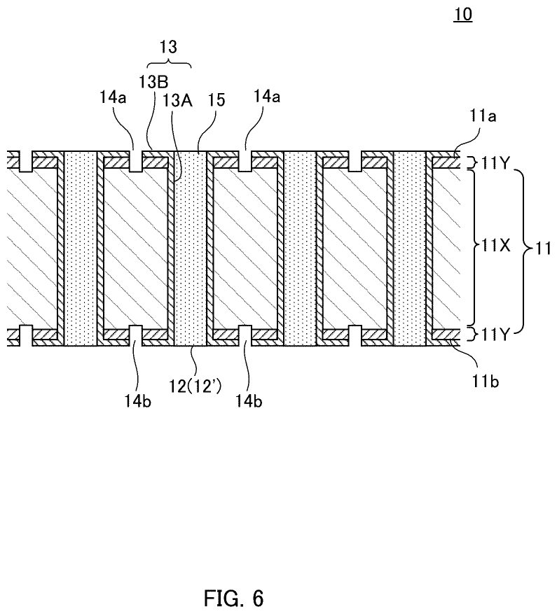

FIG. 6 is a partially enlarged cross-sectional view of an anisotropic conductive sheet according to a variation. As illustrated in FIG. 6, insulating layer 11 includes elastic layer 11X and heat-resistant resin layer 11Y.

Insulating layer 11 may include one or more elastic layers 11X and one or more heat-resistant resin layers 11Y. In the present embodiment, insulating layer 11 includes one elastic layer 11X and two heat-resistant resin layers 11Y (namely, a first heat-resistant resin layer including first surface 11a and a second heat-resistant resin layer including second surface 11b) disposed to have elastic layer 11X therebetween (see FIG. 6).

The glass transition temperature of the heat-resistant resin composition for heat-resistant resin layer 11Y is preferably higher than the glass transition temperature of the cross-linked elastomer composition for elastic layer 11X. Specifically, with electrical testing being performed at approximately −40 to 150° C., the glass transition temperature of the heat-resistant resin composition is preferably 150° C. or higher, more preferably 150 to 500° ° C. The glass transition temperature of the heat-resistant resin composition can be measured by the same method as described above.

In addition, the coefficient of linear expansion of the heat-resistant resin composition for heat-resistant resin layer 11Y is preferably lower than the coefficient of linear expansion of the cross-linked elastomer composition for elastic layer 11X. Specifically, the coefficient of linear expansion of the heat-resistant resin composition for heat-resistant resin layer 11Y is preferably 60 ppm/K or less, more preferably 50 ppm/K or less.

In addition, the storage elastic modulus of the heat-resistant resin composition for heat-resistant resin layer 11Y at 25° C. is preferably higher than the storage elastic modulus of the cross-linked elastomer composition for elastic layer 11X at 25° C.

The composition of the heat-resistant resin composition is not limited as long as the glass transition temperature, coefficient of linear expansion, and/or storage elastic modulus thereof satisfies the above range. The resin contained in the heat-resistant resin composition is preferably a heat-resistant resin whose glass transition temperature satisfies the above range. Examples of the resin contained in the heat-resistant resin composition include engineering plastics, such as polyamide, polycarbonate, polyarylate, polysulfone, polyethersulfone, polyphenylene sulfide, polyetheretherketone, polyimide, and polyetherimide, acrylic resins, urethane resins, epoxy resins, and olefin resins. The heat-resistant resin composition may further contain at least one additional component such as fillers, as necessary.

The compositions of the heat-resistant resin compositions for the two heat-resistant resin layers 11Y may be the same as or different to each other. In addition, heat-resistant resin layer 11Y including first surface 11a (or second surface 11b) is immersed in a chemical solution in, for example, an electroless plating process; thus, the heat-resistant resin composition for heat-resistant resin layer 11Y preferably has chemical resistance.

Heat-resistant resin layer 11Y may have any thickness which is preferably less than thickness Tx of elastic layer 11X (see FIG. 2), from the viewpoint of preventing the elasticity of insulating layer 11 from being impaired. Specifically, the ratio (Ty/Tx) of the thickness of heat-resistant resin layer 11Y to thickness Tx of elastic layer 11X is, for example, preferably 1/99 to 30/70, more preferably 2/98 to 10/90. When the thickness ratio of heat-resistant resin layer 11Y is at least a certain level, appropriate hardness (toughness) can be imparted to insulating layer 11 without impairing the elasticity (easiness of deformation) of insulating layer 11. As a result, such a configuration can not only improve handling properties, but also prevent damage to conductive layer 13 which would be caused by expansion and contraction of insulating layer 11 and prevent fluctuations in the center-to-center distance of the plurality of through holes 12 which would be caused by heat.

Thicknesses Ty of the two heat-resistant resin layers 11Y may be the same as or different to each other, but are preferably the same from the viewpoint of, for example, reducing the occurrence of warp of anisotropic conductive sheet 10. The ratio between the thicknesses of the two heat-resistant resin layers 11Y is, for example, preferably 0.8 to 1.2.

When the heat-resistant resin layer is disposed on the surface of anisotropic conductive sheet 10, depth d of first groove 14a (or depth d of second groove 14b) is preferably more than the thickness of heat-resistant resin layer 11Y including first surface 11a (or heat-resistant resin layer 11Y including second surface 11b). When depth d of first groove 14a (or depth d of second groove 14b) is more than the thickness of heat-resistant resin layer 11Y, heat-resistant resin layer 11Y is completely divided. Therefore, when the test object 120 is placed on anisotropic conductive sheet 10 and pushed in, the surrounding conductive layer 13 is not pushed in together, and excessive pressure concentrating on conductive filler 15 is more likely to be prevented.

That is, heat-resistant resin layer 11Y has a higher elastic modulus than elastic layer 11X, and when the depths of first groove 14a and second groove 14b are small, heat-resistant resin layer 11Y is not completely divided. Therefore, in such a case, when test object 120 is placed on or above anisotropic conductive sheet 10 and pushed in, the surrounding conductive layer 13 is also more likely to be pushed in together.

On the other hand, the depths of first groove 14a and second groove 14b are increased to completely divide heat-resistant resin layer 11Y as described above in the variation. As a result, when test object 120 is placed on anisotropic conductive sheet 10 and pushed in, the surrounding conductive layer 13 can be prevented from being pushed in as well, and the influence on the surrounding conductive layer 13 can be reduced in the variation.

Insulating layer 11 may further include at least one additional layer other than those described above, as necessary. Examples of the additional layers include, when there are two elastic layers 11X, an adhesive layer (not illustrated) disposed between the two elastic layers.

When insulating layer 11 includes heat-resistant resin layer 11Y, insulating layer 11 preferably further includes a region (non-groove region) 16 (see FIG. 1A) in which first groove 14a (or second groove 14b) is not formed in first surface 11a (or second surface 11b).

That is, when heat-resistant resin layer 11Y is completely divided by first grooves 14a (or second grooves 14b), prevention of thermal deformation (thermal expansion or thermal contraction) of elastic layer 11X may become difficult. With respect to such a problem, providing non-groove region 16 (where first groove 14a (or second groove 14b) is not formed) within a range such that the region does not hinder conduction allows heat-resistant resin layer 11Y to prevent thermal deformation of elastic layer 11X. Only one non-groove region 16 may be provided on the entire first surface 11a (or second surface 11b) (see FIG. 1A), or a plurality of non-groove regions 16 may be provided so as to surround the plurality of conductive layers 13.

In addition, the above embodiment describes an example in which one conductive layer 13 (or second conductive layer 13B) is disposed for one through hole 12 (or first conductive layer 13A) (see FIG. 1A); however, the present invention is not limited thereto.

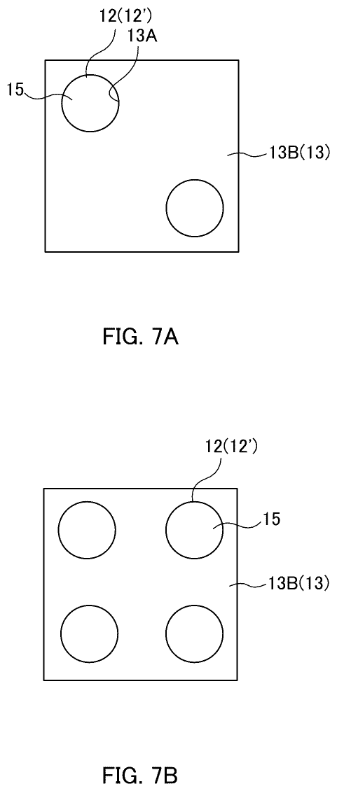

FIGS. 7A and 7B are partially enlarged plan views of the vicinities of through holes 12 on first surface 11a of anisotropic conductive sheet 10 according to a variation. As illustrated in FIGS. 7A and 7B, one conductive layer 13 (or second conductive layer 13B) may be disposed for two or more through holes 12 (or first conductive layers 13A).

The above embodiment describes an example in which, on first surface 11a (or second surface 11b), the areas or shapes of at least some of the plurality of second conductive layers 13B (or conductive layers 13) are equal to each other; however, the present invention is not limited thereto.

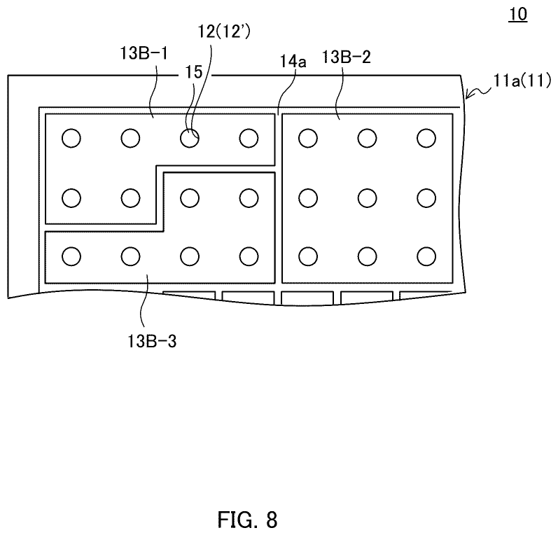

FIG. 8 is a partially enlarged plan view of first surface 11a of anisotropic conductive sheet 10 according to a variation. As illustrated in FIG. 8, at least some of the plurality of second conductive layers 13B (or conductive layers 13) may have different areas or shapes in accordance with the type of test object 120. For example, in a chip (namely, one type of test object 120), a plurality of terminals may be assigned for the same signal. In such a case, one large second conductive layer 13B (13B-1, 13B-2, or 13B-3) is preferably be formed for each set of terminals to which the same signal is assigned (that is, for each set of through holes 12) (see FIG. 8) rather than forming one second conductive layer 13B for each terminal of the chip (that is, for each through hole 12) (see FIG. 1A). For example, the following configuration is possible: second conductive layer 13B-1 corresponds to the ground (GND), and second conductive layer 13B-3 corresponds to a power supply line. As a result, the resistance value between the terminals can be reduced during electrical testing, thereby increasing resistance to noise and stabilizing the potential. This configuration thus is more likely to improve testing accuracy.

The above embodiment describes an example in which second conductive layer 13B is disposed on the first surface 11a and also on second surface 11b; however, the present invention is not limited thereto. For example, second conductive layer 13B does not necessarily be disposed on first surface 11a or second surface 11b, or may be disposed only on one of first surface 11a and second surface 11b.

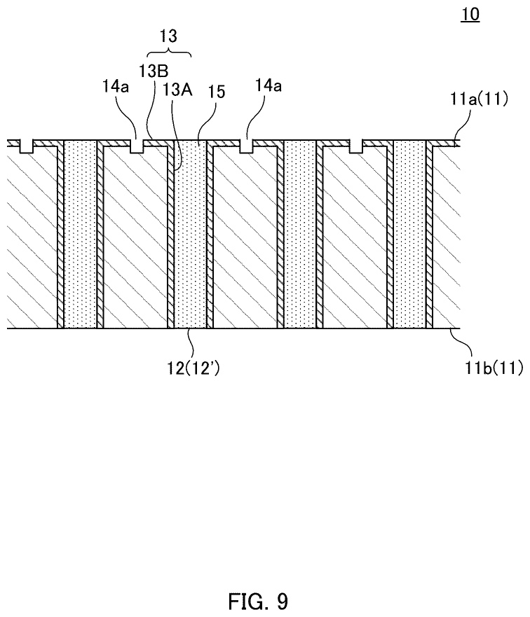

FIG. 9 is a partially enlarged cross-sectional view of anisotropic conductive sheet 10 according to a variation. As illustrated in FIG. 9, second conductive layer 13B may be disposed only on one of first surface 11a and second surface 11b.

The above embodiment describes an example in which the anisotropic conductive sheet is used for electrical testing; however, the present invention is not limited thereto. The anisotropic conductive sheet can also be used for electrical connection between two electronic members, such as between a glass board and a flexible printed circuit board, or between a board and an electronic component mounted on the board.

### EXAMPLES

Hereinafter, the invention will be descried with reference to Example. The scope of the present invention is not interpreted to be limited by the Example.

### 1. Preparation of Conductive Elastomer Composition

ThreeBond 3303B (containing Ag particles, silicone rubber, and crosslinking agent) manufactured by ThreeBond Co., Ltd. was prepared as a conductive elastomer composition.

### Measurement of Storage Elastic Modulus

First, the conductive elastomer composition was heated at 170° C. for 30 minutes to obtain a cross-linked product with a film thickness of 4 mm. The storage elastic modulus of the obtained cross-linked product was measured at 25° C. in a compressive deformation mode in accordance with JIS K 7244-1:1998/ISO6721-1:1994, and was found to be 2.8 MPa.

### Measurement of Volume Resistivity

The volume resistivity of the cross-linked conductive elastomer composition obtained from the above was measured by the method described in ASTM D 991, and was found to be 3× 10₋₅ Ω·m.

### 2. Production and Evaluation of Anisotropic Conductive Sheet

### Example 1

As an insulating sheet, a silicone rubber sheet including a plurality of through holes 12 (equivalent circle diameter of the openings of the plurality of through holes 12 on the first surface 11a side is 85 μm) was prepared. A continuous gold (Au) layer was formed on the surface of this sheet (the inner wall surfaces of through holes 12, first surface 11a, and second surface 11b) by a plating method. Next, a conductive elastomer composition is dropped to first surface 11a of the obtained sheet, and the conductive elastomer composition is poured into to fill cavities 12′ corresponding to through holes 12 with vacuuming being performed from the second surface 21b side. Thereafter, the conductive elastomer composition was cross-linked (cured) by heating at 170° C. A plurality of first grooves 14a and a plurality of second grooves 14b were formed in first surface 11a and second surface 11b of the obtained sheet, respectively, and the conductive layer was divided into a plurality of conductive layers 13. As a result, an anisotropic conductive sheet was obtained.

### Comparative Example 1

An anisotropic conductive sheet was obtained in the same manner as in Example 1, except that the conductive elastomer composition did not fill cavities 12′ corresponding to through holes 12 of the sheet.

### Evaluation

A durability test was conducted on the obtained anisotropic conductive sheets, and the resistance value after the durability test was evaluated as follows.

### Durability Test

As illustrated in FIG. 5A, guide pins 110A of testing board 110 were inserted through the positioning holes (not illustrated) of anisotropic conductive sheet 10, thereby positioning and disposing anisotropic conductive sheet 10 at testing board 110. On or above this anisotropic conductive sheet 10, test chip 120 was disposed as a test object, and the sheet and chip were fixed with a pressing jig.

As test chip 120, used was an object in which total of 264 solder ball electrodes (material of lead-free solder) with a diameter of 0.2 mm and a height of 0.17 mm are arranged at a pitch of 0.3 mm, and every two of the solder ball electrodes are electrically connected to each other by wiring inside test chip 120 (see FIG. 5B).

Next, at 25° C., a load of 3 kg was applied to test chip 120 by using a pressure jig, and then the pressure was released. This operation was defined as one pressurization cycle, and after repeating the pressurization cycle a predetermined number of times at 30 rpm, the electrical resistance value was measured.

### Measurement of Electrical Resistance Value

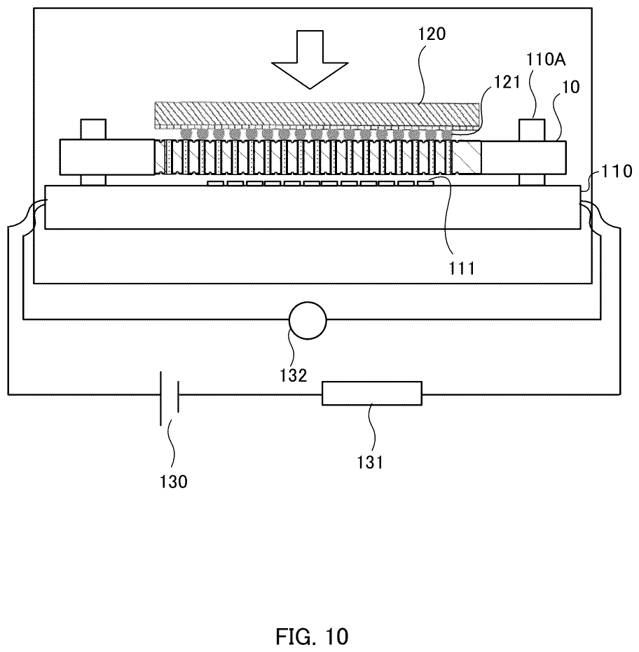

The electrical resistance value was measured by the following method. Between external terminals (not illustrated) of testing board 110 that are electrically connected to each other via anisotropic conductive sheet 10, test chip 120, and electrodes 111 (test electrodes) of testing board 110 and their wiring (not illustrated), DC power supply 130 and constant current control device 131 constantly applied a DC current of 10 mA, and voltmeter 132 measured the voltage between the external terminals of testing board 110 during pressurization (see FIG. 10). Electrical resistance value R₁ was determined by the following equation, where Vi is defined as the measured voltage value (V) and I₁ (=10 mA) is defined as the applied direct current.

$${R}_{1} = {V}_{1} / {I}_{1} \qquad Equation 1$$

Electrical resistance value R₁ includes, in addition to the electrical resistance values of the two conductive layers 13 and 13, the electrical resistance value between the electrodes of test chip 120 and the electrical resistance value between the external terminals of testing board 110.

Electrical resistance values R₁ were then measured for conductive layers 13 of the anisotropic conductive sheet contacting 264 electrodes of the solder balls, and the average of the electrical resistance value was determined.

Table 1 shows the evaluation results.

TABLE 1

| | After 10 | After 100 | After 1000 |
|---|---|---|---|
| | cycles | cycles | cycles |
| Example 1 | 59 | 66 | 96 |
| Comparative Example 1 | 143 | 156 | 750 |

As shown in Table 1, by filling the plurality of cavities 12′ (each surrounded by conductive layer 13) with a cross-linked conductive elastomer composition, the increase in resistance value (average value) after the pressurization cycles can be reduced as compared to Comparative Example 1.

This application is entitled to and claims the benefit of Japanese Patent Application No. 2021-126025 filed on Jul. 30, 2021, the disclosure of which including the specification and drawings is incorporated herein by reference in its entirety.

### INDUSTRIAL APPLICABILITY

The present invention is capable of providing an anisotropic conductive sheet that can prevent cracking and peeling off of the conductive layer thereof and maintain satisfactory conductivity even after repeated pressurization and depressurization during the pushing process, and an electrical testing method using the anisotropic conductive sheet.

### REFERENCE SIGNS LIST

10 Anisotropic conductive sheet
11 Insulating layer
11a First surface
11b Second surface
11X Elastic layer
11Y Heat-resistant resin layer
12 Through hole
12′ Cavity
13 Conductive layer
14a First groove
14b Second groove
15 Conductive filler
21 Insulating sheet
22 Conductive layer
100 Electrical testing apparatus
110 Testing board
111 Electrode
120 Test object
121 Terminal (of test object)
L Conductive elastomer composition

1. An anisotropic conductive sheet, comprising:
an insulating layer including a first surface located on one side in a thickness direction of the insulating layer, a second surface located on another side in the thickness direction, and a plurality of through holes each extending between the first surface and the second surface;
a plurality of first conductive layers respectively disposed on inner wall surfaces of the plurality of through holes;
a plurality of conductive fillers respectively filling cavities inside the plurality of through holes, each of the cavities being surrounded by a corresponding one of the first conductive layers,
wherein
each of the plurality of conductive fillers contains a cross-linked product of a conductive elastomer composition that contains a conductive particle and an elastomer.

2. The anisotropic conductive sheet according to claim 1, further comprising:
a plurality of second conductive layers disposed on or above the first surface and the second surface, each of the plurality of second conductive layers communicating with one or more of the first conductive layers;
on or above the first surface, a plurality of first grooves disposed between the plurality of second conductive layers and configured to insulate the plurality of second conductive layers from each other; and
on or above the second surface, a plurality of second grooves disposed between the plurality of second conductive layers and configured to insulate the plurality of second conductive layers from each other.

3. The anisotropic conductive sheet according to claim 1, wherein:
the insulating layer contains a cross-linked product of an elastomer composition; and
a storage elastic modulus of the cross-linked product of the conductive elastomer composition at 25° C. is higher than a storage elastic modulus of the cross-linked product of the elastomer composition in the insulating layer at 25° C.

4. The anisotropic conductive sheet according to claim 1, wherein
a storage elastic modulus of the cross-linked product of the conductive elastomer composition at 25° C. is 1 to 300 MPa.

5. The anisotropic conductive sheet according to claim 1, wherein
the elastomer contained in the conductive elastomer composition is silicone rubber.

6. The anisotropic conductive sheet according to claim 1, wherein
a volume resistivity of the cross-linked product of the conductive elastomer composition is 10⁻² Ω·m or less.

7. The anisotropic conductive sheet according to claim 1, wherein
the conductive particle contains at least one metal selected from the group consisting of gold, silver, and copper.

8. The anisotropic conductive sheet according to claim 1, wherein
the first conductive layer contains at least one metal selected from the group consisting of gold, silver, and copper.

9. The anisotropic conductive sheet according to claim 2, wherein
the insulating layer contains:
an elastic layer containing a cross-linked product of an elastomer composition, and
a heat-resistant resin layer containing a heat-resistant resin composition having a higher glass transition temperature than the cross-linked product of the elastomer composition.

10. The anisotropic conductive sheet according to claim 9, wherein
a storage elastic modulus of the heat-resistant resin composition at 25° C. is higher than a storage elastic modulus of the cross-linked product of the elastomer composition in the insulating layer at 25° C.

11. The anisotropic conductive sheet according to claim 9, wherein
the insulating layer includes:
a first heat-resistant resin layer including the first surface and containing the heat-resistant resin composition,
a second heat-resistant resin layer including the second surface and containing the heat-resistant resin composition, and
the elastic layer disposed between the first heat-resistant resin layer and the second heat-resistant resin layer.

12. The anisotropic conductive sheet according to claim 11, wherein:
a depth of the first groove is more than a thickness of the first heat-resistant resin layer; and
a depth of the second groove is more than a thickness of the second heat-resistant resin layer.

13. The anisotropic conductive sheet according to claim 12, wherein
at least some of the plurality of second conductive layers have different areas or shapes from each other.

14. The anisotropic conductive sheet according to claim 1, wherein:
the anisotropic conductive sheet is used for electrical testing of a test object; and
the test object is disposed on or above the first surface.

15. A method for producing an anisotropic conductive sheet, the method comprising:
preparing an insulating layer including a first surface located on one side in a thickness direction of the insulating layer, a second surface located on another side in the thickness direction, and a plurality of through holes each extending between the first surface and the second surface;
forming a conductive layer continuously on inner wall surfaces of the plurality of through holes and on the first surface;
filling insides of the plurality of through holes of the insulating layer with a conductive elastomer composition containing a conductive particle and an elastomer, the insulating layer being an insulating layer on which the conductive layer is formed; and
forming a plurality of first grooves on or above the first surface of the insulating layer filled with the conductive elastomer composition or with a cross-linked product of the conductive elastomer composition, and dividing the conductive layer into a plurality of conductive layers.

16. An electrical testing apparatus, comprising:
a testing board including a plurality of electrodes; and
the anisotropic conductive sheet according to claim 1 disposed on or above a surface of the testing board, the surface being a surface on which the plurality of electrodes are disposed.

17. An electrical testing method, comprising:
stacking, via the anisotropic conductive sheet according to claim 1, a testing board including an electrode, and a test object including a terminal, and electrically connecting the electrode of the testing board with the terminal of the test object via the anisotropic conductive sheet.
